(19) United States
(12) Patent Application Publication
(10) Pub. No.: US 2009/0246542 A1
(43) Pub. Date: Oct. 1, 2009

(54) PLASMA PROCESS APPARATUS, PLASMA PROCESS METHOD, AND OBJECT PROCESSED BY THE PLASMA PROCESS METHOD

(75) Inventors: Ken Nakao, Nirasaki-Shi (JP); Shuji Moriya, Nirasaki-Shi (JP); Hiroyuki Kousaka, Nagoya-Shi (JP)

Correspondence Address: IPUSA, P.L.L.C, 1054 31ST STREET, N.W., Suite 400, Washington, DC, 20007, US

(73) Assignees: TOKYO ELECTRON LIMITED; National University Corporation Nagoya University

(21) Appl. No.: 12/410,492

(22) Filed: Mar. 25, 2009

(30) Foreign Application Priority Data
Mar. 26, 2008 (JP) 2008-081840

(51) Int. Cl. B32B 15/04; C23C 16/513

(52) U.S. Cl. 428/457; 118/723 R; 427/569

(57) ABSTRACT

A disclosed plasma process apparatus includes an electromagnetic wave generator that generates electromagnetic waves; a vacuum vessel configured to be hermetically connected with an object to be processed, and evacuated to reduced pressures along with the object to be processed hermetically connected to the vacuum vessel; an electromagnetic wave guiding portion configured to guide the electromagnetic waves generated by the electromagnetic wave generator so that plasma is ignited in the vacuum vessel; a gas supplying portion configured to supply a process gas to the object to be processed hermetically connected to the vacuum vessel; an evacuation portion configured to evacuate the object to be processed hermetically connected to the vacuum vessel; and a voltage source configured to apply a predetermined voltage to the object to be processed hermetically connected to the vacuum vessel so that the plasma ignited in the vacuum vessel is guided to the object to be processed.

### BACKGROUND OF THE INVENTION

1. Field of the Invention

The present invention relates to a plasma process apparatus that processes an object, which is to be processed by plasma, in a vacuum system of the plasma process apparatus and introduces plasma into an inner space of the object to be processed, thereby depositing a film on an inner surface of the object to be processed.

2. Description of the Related Art

An apparatus has been proposed which can deposit a film on an inner surface of a tubular member by plasma. For example, a film deposition technique has been known that employs an apparatus where a tubular workpiece material and a rod-shaped target are concentrically arranged in a vacuum vessel. In this vacuum vessel, plasma is ignited by Electron Cyclotron Resonance (ECR) at the end portion of the vacuum vessel, and a plasma sheath is formed around the periphery of the target by applying a negative bias voltage to the target. With this, the target is sputtered with plasma particles generated by the plasma sheath, thereby depositing a film on the inner surface of the tubular workpiece material (for example, see Patent Document 1).

In addition, it has been known that a film is deposited on an inner surface of a duct by using plasma generated by a hollow cathode (for example, see Patent Document 2).

Patent Document 1: Japanese Patent Application Laid-Open Publication No. 2004-47207.

Patent Document 2: U.S. Pat. No. 7,300,684.

In recent years, it has been proposed to deposit a film on an inside surface of ducts and the like to be employed in semiconductor fabrication apparatuses and the like in order to enhance corrosion resistance of such ducts. Because highly reactive gases or toxic gases may be used in a semiconductor fabrication process, there will be increasing demands for such ducts having a highly corrosion resistive coating film on the inner surface.

However, the above conventional process technique faces a problem in that workpiece materials larger than the vacuum vessel cannot be processed, because the film deposition is carried out in the vacuum vessel. In addition, it is difficult to make a vacuum vessel large enough to accommodate large workpiece materials that can be used as the ducts and the like in the semiconductor fabrication apparatuses.

Moreover, because a tubular workpiece material is placed in the vacuum vessel, not only the inner surface but also an outer surface of the tubular workpiece material is covered with the coating film. Because the outer surface is not exposed to the corrosive gases, the coating film on the outer surface may lead to a waste of raw materials of the coating film.

Moreover, because an applied voltage tends to be higher in a film deposition method employing a hollow cathode plasma, plasma density is likely to be uneven along the axial direction.

For example, when depositing the coating film on the inner surface of an object to be processed having a high aspect ratio such as a long and narrow duct, the plasma density becomes lower in a central part of the object to be processed, because the central part is far away from the anode. Therefore, the coating film cannot be uniform along the longitudinal direction of the object to be processed.

### SUMMARY OF THE INVENTION

The present invention is directed to a plasma process apparatus that is capable of depositing a coating film on an inner surface of a tubular member having a sufficient length that can be used as a duct, or an inner surface of a member having a complicated inner shape, a plasma process method carried out in the plasma process apparatus, and an object processed by the plasma process method.

According to a first aspect of the present invention, there is provided a plasma process apparatus for processing an object to be processed. This plasma process apparatus includes an electromagnetic wave generator that generates electromagnetic waves; a vacuum vessel configured to be hermetically connected with an object to be processed, and evacuated to reduced pressures along with the object to be processed hermetically connected to the vacuum vessel; an electromagnetic wave guiding portion configured to guide the electromagnetic waves generated by the electromagnetic wave generator so that plasma is ignited in the vacuum vessel; a gas supplying portion configured to supply a process gas to the object to be processed; an evacuation portion configured to evacuate the object to be processed; and a voltage source configured to apply a predetermined voltage to the object to be processed so that the plasma ignited in the vacuum vessel is guided to the object to be processed.

According to a second aspect of the present invention, there is provided a plasma process apparatus according to the first aspect, wherein the voltage source may be connected to an exterior of the object to be processed.

According to a third aspect of the present invention, there is provided a plasma process apparatus according to the first or the second aspect, wherein the voltage source applies the predetermined voltage in order to generate a sheath in an inner space of the object to be processed so that an inner surface of the object to be processed is processed by electromagnetic waves guided into the inner space of the object to be processed by the sheath.

According to a fourth aspect of the present invention, there is provided a plasma process apparatus according to any one of the first through the third aspects, wherein the vacuum vessel is formed of a dielectric material in a tubular shape and has an electrically conductive tube accommodating the vacuum vessel, and wherein the electromagnetic wave guiding portion surrounds the electrically conductive tube so that a gap is made between the electromagnetic wave guiding portion and the electrically conductive tube so that the electromagnetic waves are guided through the gap, thereby applying an electric field generated in the gap to the vacuum vessel.

According to a fifth aspect of the present invention, there is provided a plasma process apparatus according to the fourth aspect. The plasma process apparatus further includes a waveguide that guides the electromagnetic waves generated by the electromagnetic wave generator toward the electromagnetic wave guiding portion, wherein the vacuum vessel is arranged in order to extend from an inside to an outside of the waveguide in a direction orthogonal to a direction along which the electromagnetic waves propagate, wherein the electrically conductive tube surrounds the vacuum vessel inside the waveguide, wherein the electromagnetic wave guiding portion is configured as a protruding portion of the waveguide, and wherein the vacuum vessel has a portion that is not surrounded by the electrically conductive tube, the portion being inside the protruding portion of the waveguide, so that the electric field generated in the gap between the electromagnetic wave guiding portion and the electrically conductive tube is applied to the inner space of the vacuum vessel through the portion not surrounded by the electrically conductive tube.

According to a sixth aspect of the present invention, there is provided a plasma process apparatus according to the fourth aspect. The plasma process apparatus further includes a waveguide that guides the electromagnetic waves generated by the electromagnetic wave generator toward the electromagnetic wave guiding portion, wherein the vacuum vessel penetrates through the waveguide in a direction orthogonal to an electromagnetic wave propagation direction, wherein the electrically conductive tube surrounds the vacuum vessel inside the waveguide, wherein the electromagnetic wave guiding portion is configured as a protruding portion of the waveguide, and wherein the vacuum vessel has a portion that is not surrounded by the electrically conductive tube, the portion being inside the protruding portion of the waveguide, so that the electric field generated in the gap between the electromagnetic wave guiding portion and the electrically conductive tube is applied to the inner space of the vacuum vessel through the portion not surrounded by the electrically conductive tube.

According to a seventh aspect of the present invention, there is provided a plasma process apparatus according to any one of the first through the six aspects, wherein the voltage source applies a pulse voltage as the predetermined voltage to the object to be processed.

According to an eighth aspect of the present invention, there is provided a plasma process apparatus according to the seventh aspect, further comprising a synchronization circuit connected to the source voltage and the electromagnetic wave generator, wherein a frequency of the pulse voltage applied to the object to be processed is the same as a frequency of the electromagnetic waves generated by the electromagnetic wave generator; and wherein the pulse voltage is synchronized with the electromagnetic waves by the synchronization circuit.

According to a ninth aspect of the present invention, there is provided a plasma process apparatus according to any one of the first through the eighth aspects, wherein a density of the plasma guided to the object to be processed is 1.0×10¹¹ cm⁻³ or more.

According to a tenth aspect of the present invention, there is provided a plasma process apparatus according to any one of the first through the ninth aspects, wherein a frequency of the electromagnetic waves is from 50 MHz through 50 GHz.

According to an eleventh aspect of the present invention, there is provided a plasma process apparatus according to any one of the first through the eighth aspects, wherein a frequency of the electromagnetic waves is 2.45 GHz and a density of the plasma that is ignited by the electromagnetic waves and guided to the object to be processed is 1.0×10¹¹ cm⁻³ or more.

According to a twelfth aspect of the present invention, there is provided a plasma process apparatus according to any one of the first through the eleventh aspects, wherein the vacuum vessel is made of ceramics or quartz.

According to a thirteenth aspect of the present invention, there is provided a plasma process apparatus according to any one of the first through the twelfth aspects, wherein the process gas includes a chemical group containing a carbon atom.

According to a fourteenth aspect of the present invention, there is provided a plasma process apparatus according to any one of the first through the thirteenth aspects, wherein the process gas includes tetramethylsilane.

According to a fifteenth aspect of the present invention, there is provided a plasma process method including steps of guiding electromagnetic waves to a vacuum vessel so that plasma is ignited in the vacuum vessel; supplying a process gas to an inner space of an object to be processed; evacuating the inner space of the object to be processed; and applying a predetermined voltage to the object to be processed so that the plasma is guided to the inner space of the object to be processed, thereby processing an inner surface of the object to be processed.

According to a sixteenth aspect of the present invention, there is provided a plasma process method according to the fifteenth aspect, wherein a sheath is formed in the inner space of the object to be processed in the step of applying the predetermined voltage to the object to be processed.

According to a seventeenth aspect of the present invention, there is provided an object processed by a plasma process method. The method includes steps of guiding electromagnetic waves to a vacuum vessel so that plasma is ignited in the vacuum vessel; supplying a process gas to an inner space of the object to be processed; evacuating the inner space of the object to be processed; and applying a predetermined voltage to the object to be processed so that the plasma is guided to the inner space of the object to be processed, thereby processing an inner surface of the object to be processed.

According to an eighteenth aspect of the present invention, there is provided an object processed by the plasma process method, according to the seventeenth aspect, wherein the object to be processed is made of stainless steel.

According to a nineteenth aspect of the present invention, there is provided an object processed by the plasma process method, according to the seventeenth or the eighteenth aspect, wherein the object is used in an atmospheric environment.

According to a twentieth aspect of the present invention, there is provided an object processed by the plasma process method, according to any one of the seventeenth through the nineteenth aspects, wherein the object has a curved portion.

According to embodiments of the present invention, there are provided a plasma process apparatus that is capable of depositing a coating film only on an inner surface of a tubular member having a sufficient length that can be used as a duct, and an inner surface of a member having a complicated inner shape, a plasma process method carried out in the plasma process apparatus, and an object processed by the plasma process method.

### BRIEF DESCRIPTION OF THE DRAWINGS

FIG. 1 is a schematic view of a plasma process apparatus according to a first embodiment of the present invention;

FIG. 2 is a partial enlarged view for explaining the principle of plasma ignition in the plasma process apparatus according to the first embodiment of the present invention;

FIG. 3A is a partial enlarged view for explaining the principle of guiding plasma in the plasma process apparatus according to the first embodiment of the present invention, where the plasma generated before a pulse voltage is applied to a metal tube is illustrated;

FIG. 3B is a partial enlarged view for explaining the principle of guiding plasma in the plasma process apparatus according to the first embodiment of the present invention, where the plasma generated after a pulse voltage is applied to a metal tube is illustrated;

FIG. 4 is a schematic view illustrating a primary portion of the plasma process apparatus according to the first embodiment of the present invention, which is used for a bent tubular member;

FIG. 5 is a schematic view of a primary portion of a plasma process apparatus according to a second embodiment of the present invention;

FIG. 6 is a schematic view of a primary portion of a plasma process apparatus according to a third embodiment of the present invention; and

FIG. 7 is a schematic view illustrating an alternative example of the primary portion of the plasma process apparatus according to the third embodiment of the present invention.

### DETAILED DESCRIPTION OF THE PREFERRED EMBODIMENTS

Referring to the accompanying drawings, a plasma process apparatus, a plasma process method, and an object processed by the method according to an embodiment of the present invention will be described. In the drawings, the same or corresponding reference marks are given to the same or corresponding members or components. The drawings are illustrative of the invention, and there is no intention to indicate scale or relative proportions among the members or components. Therefore, the specific size should be determined by a person having ordinary skill in the art in view of the following non-limiting embodiments.

It should be noted that “plasma ignition area” is mainly used here to express the following. When a dielectric body, whose inner space is evacuated to a vacuum, is surrounded by electrically conductive materials that are arranged with a gap in a longitudinal direction of the dielectric body, and electromagnetic waves are applied to the gap, the electromagnetic waves penetrate through the gap into the inner space of the dielectric body, thereby igniting plasma mainly at and around a midpoint of the gap in the inner space of the dielectric body. The area where the plasma is ignited is referred to as the plasma ignition area.

In addition, “electromagnetic wave-excited plasma” is used here to express plasma where an ionization state is maintained by ionization energy from the electromagnetic waves.

Moreover, “surface wave-excited plasma” is used here to express plasma where an ionization state is maintained by ionization energy from electromagnetic waves of a surface wave mode, which propagate along a boundary between the plasma and the inner surface of a dielectric body. This plasma has an electron density more than or equal to the minimum electron density that allows the surface waves to propagate. The minimum electron density is determined by the frequency of the applied electromagnetic waves and the dielectric constant of a dielectric material with which the plasma is in contact.

Furthermore, “sheath” is used here to express an area covering a solid wall in contact with plasma, the area having a positive ion density greater than an electron density and thus an overall excess positive charge. Such an area is formed because an electric field is caused to attract positive ions into the solid wall when quasi-neutral plasma, where the electron and positive ion densities are balanced in bulk, comes in contact with the solid wall.

### First Embodiment

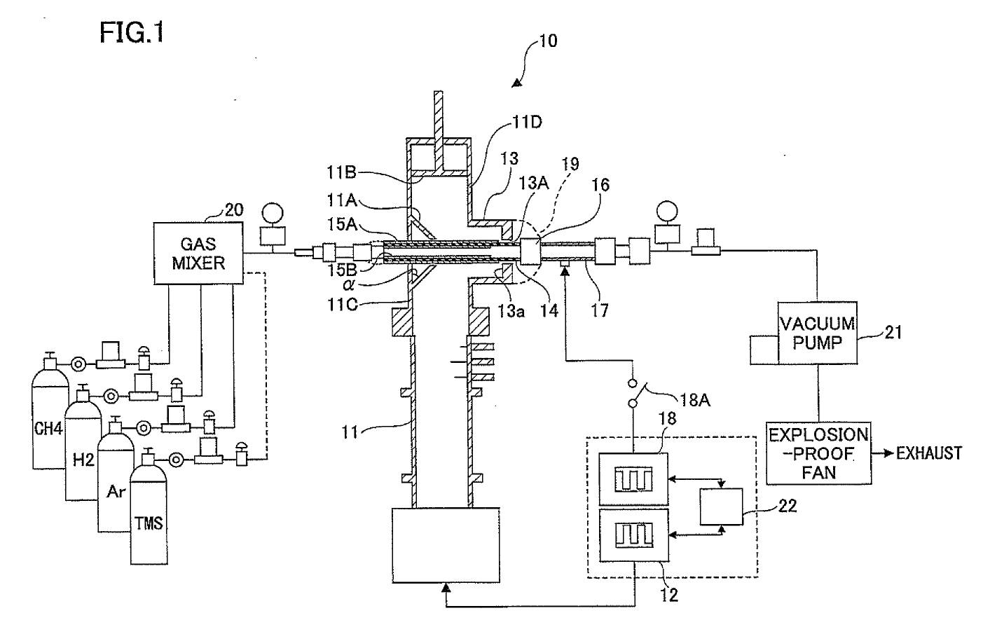

FIG. 1 is a schematic view of a plasma process apparatus according to a first embodiment of the present invention.

As shown in FIG. 1, a plasma process apparatus 10 according to the first embodiment includes a waveguide column 11, an electromagnetic wave generator 12 connected to the waveguide column 11, a guiding portion 13 that protrudes outward from a side wall of the waveguide column 11 and guides electromagnetic waves to the right in FIG. 1, a quartz tube 14 that penetrates through the waveguide column 11, an electrically conductive tube 15A accommodating the quartz tube 14, an electrically conductive tube 15B inserted into the quartz tube 14, a pulse voltage generator 18 that applies a pulse voltage to a metal tube 17 hermetically connected to the quartz tube 14 via a joint 16, and a metal mesh 19 that prevents the electromagnetic waves from leaking outward.

The waveguide column 11 is made of a hollow metal tube having a rectangular cross section and allows the electromagnetic waves of 2.45 GHz supplied from the electromagnetic wave generator 12 to propagate inside the waveguide column 11 in this embodiment.

A cone-shaped reflector 11A is attached on the inner wall of the waveguide column 11. A plunger 11B is arranged at one end of the waveguide column 11.

The reflector 11A is cone-shaped and reflects the electromagnetic waves, which are supplied from the electromagnetic generator 12 and propagate inside the waveguide column 11, in a direction orthogonal to a direction (incoming direction) in which the electromagnetic waves originally propagate. An apex end opening of the reflector 11A allows the quartz tube 14 and the electrically conductive tube 15A to pass through so that the cone-shaped reflector 11A, the quartz tube 14, the electrically conductive tube 15A, and the guiding portion 13 share a center axis. An angle α defined by an inner circumferential surface of the reflector 11A and a side wall 11C of the waveguide column 11 is configured to be about 45° in this embodiment.

In the waveguide column 11 having the reflector 11A, part of the electromagnetic waves propagating upwardly inside the waveguide column 11 in FIG. 1 are reflected by the reflector 11A and guided to the right in the drawing. Namely, the electromagnetic waves are guided in a direction orthogonal to the (incoming) direction in which the electromagnetic waves originally propagate.

In addition, the electromagnetic waves that are reflected by the plunger 11B and thus propagate downwardly in the waveguide column 11 are also guided to the right in FIG. 1 by the reflector 11A.

As stated above, the electromagnetic waves propagating inside the waveguide column 11 are reflected to the right by the reflector 11A and guided to the guiding portion 13.

The electromagnetic wave generator 12 generates electromagnetic waves of 2.45 GHz and is required to generate the electromagnetic waves at sufficient power to generate plasma with a sufficient density that can deposit, for example, a diamond film on the inner surface of the metal tube 17. For example, the electromagnetic wave generator 12 is configured to output the electromagnetic waves of 1.3 kW in this embodiment. The frequency of the electromagnetic waves generated by the electromagnetic wave generator 12 is not limited to 2.45 GHz, but preferably may be in a range from 50 MHz to 50 GHz.

The guiding portion 13 is a hollow metal waveguide tube that protrudes outward from the side wall 11D of the waveguide column 11 and guides the electromagnetic waves inside the waveguide column 11 to the right in FIG. 1. The guiding portion 13 has substantially a shape of a cylinder with a bottom 13a and has a constant inner diameter along the longitudinal direction.

In addition, an opening 13A is formed in the bottom 13a of the guiding portion 13, which allows the quartz tube 14 to extend outward through the opening 13A.

As stated, the reflector 11A and the guiding portion 13 serve as an electromagnetic guiding portion that guides the electromagnetic waves in the waveguide column 11 in the direction orthogonal to the incoming direction.

The quartz tube 14 is configured as a tubular vacuum vessel whose inner space can be maintained at a vacuum, and penetrates through the left side wall 11C of the waveguide column 11, the apex end opening of the reflector 11A, the opening 13A of the guiding portion 13, and the right side wall 11D of the waveguide column 11. The right end of the quartz tube 14 is connected to a joint 16 outside of the opening 13A, and the left end of the quartz tube 14 is connected to a gas mixer 20. In alternative embodiments, a ceramic tube may be used instead of the quartz tube 14.

An outer circumference of the quartz tube 14, except for an area near the opening 13A of the guiding portion 13, is covered with the electrically conductive tube 15A. The area near the opening 13A is not covered with the electrically conductive tube 15A, and serves as an uncovered portion described later. Quartz has a relative dielectric constant of about 3.7.

The electrically conductive tube 15A is a tubular conductive member that covers the outer circumference of the quartz tube 14, and is made of, for example, copper (Cu). The electrically conductive tube 15A covers the outer circumference of the quartz tube 14, except for the area near the opening 13A, inside the waveguide column 11 and the guiding portion 13.

The electrically conductive tube 15B is a tubular conductive member that covers an inner circumferential surface of the quartz tube 14, and is made of, for example, Cu. The electrically conductive tube 15B has a shorter longitudinal length than the electrically conductive tube 15A. Specifically, the right end of the electrically conductive tube 15B is located at a position closer to the side wall 11D of the waveguide column 11 from the uncovered portion of the quartz tube 14 where the quartz tube 14 is not covered with the electrically conductive tube 15A. In other words, the right end of the electrically conductive tube 15B, while being inside the guiding portion 13, is located at a position closer to the side wall 11D of the waveguide column 11 than a position where the right end of the electrically conductive tube 15A is located.

The center axes of the cone-shaped reflector 11A, the guiding portion 13, the quartz tube 14, and the electrically conductive tube 15A coincide with one another.

The joint 16 is made of metal and connects the quartz tube 14 to the metal tube 17.

The metal tube 17 is an object to be processed. Namely, a coating film, for example, a diamond thin film is deposited on the inner surface of the metal tube 17. For example, the metal tube 17 is made of stainless steel. The metal tube 17 may a tubular member having a length of 100 mm, an outer diameter of 6.35 mm, and an inner diameter of 4.35 mm, which is one example of tubular members to be used as standardized ducts according to Japanese Industrial Standard.

The left end of the metal tube 17 is connected to the quartz tube 14 via the joint 16, and the right end of the metal tube 17 is connected to a vacuum pump 21. The inner spaces of the metal tube 17 and the quartz tube 14 may be evacuated and maintained at a vacuum of about 1.0 Pa. Namely, the metal tube 17 itself provides a vacuum environment.

In addition, the metal tube 17 is connected to a pulse voltage source 18 by which a pulsed negative voltage is applied to the metal tube 17, and thus a sheath is formed along the inner surface of the metal tube 17. The relative dielectric constant of the sheath formed along the inner surface of the metal tube 17 is about 1.0. Namely, the sheath serves as a dielectric layer on the inner surface of the metal tube 17.

The pulse voltage source 18 applies the negative pulse voltage to the metal tube 17 in order to form the sheath along the inner surface of the metal tube 17. Specifically, the pulse voltage source 18 is connected to the outer portion (outer circumference) of the metal tube 17, and thus the negative pulse (square wave-like) voltage is applied to the metal tube 17 from the outer circumference of the metal tube 17. In this embodiment, a voltage of about −200 V at a frequency of about 200 Hz is applied to the metal tube 17 at a duty ratio of about 3%. A switch 18A is provided between the metal tube 17 and the pulse voltage source 18.

The metal mesh 19 is made of copper and provided between the guiding portion 13 and the joint 16 in order to cover the uncovered portion of the quartz tube 14 so that the uncovered portion of the quartz tube 14 is substantially surrounded by the metal mesh 19. The metal mesh 19 absorbs the electromagnetic waves emitted from the opening 13A of the guiding portion. 13, thereby reducing outward leakage of the electromagnetic waves.

The gas mixer 20 mixes gases supplied to the inner spaces of the quartz tube 14 and the metal tube 17 evacuated to a vacuum. As process gases, methane (CH₃), hydrogen (H₂), argon (Ar), and tetramethylsilane (TMS) are introduced into the gas mixer 20 in this embodiment.

The vacuum pump 21 evacuates the inner spaces of the quartz tube 14 and the metal tube 17 to a vacuum. For example, as the vacuum pump 21, a rotary pump may be used that is capable of evacuating the inner spaces to an ultimate vacuum of about 1.0 Pa.

The gases evacuated by the vacuum pump 21 are finally vented to atmosphere through an explosion-proof fan.

In addition, a pulse synchronization circuit 22 is connected between the electromagnetic wave generator 12 and the pulse voltage source 18, and allows the pulse voltage source 18 to synchronize the negative pulse voltage with the electromagnetic waves generated by the electromagnetic wave generator 12.

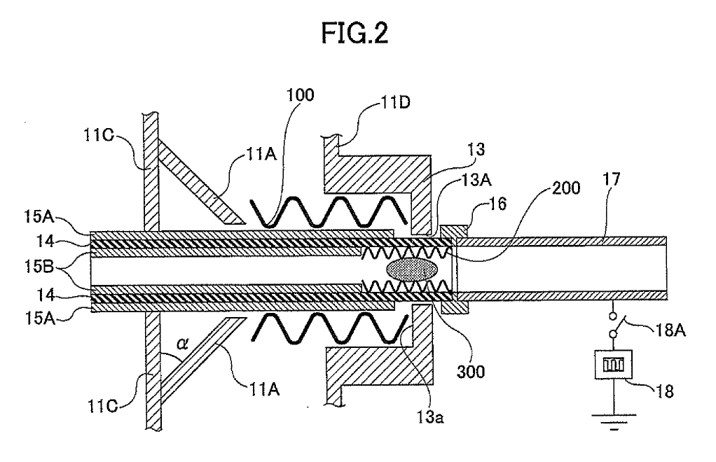

FIG. 2 is a partial enlarged view for explaining the principle of plasma ignition in the plasma process apparatus according to the first embodiment of the present invention. In the following explanation, the process gases (CH₄, H₂, Ar, TMS) are flowing through the quartz tube 14 and the metal tube 17 from left to right.

In FIG. 2, the switch 18A between the metal tube 17 and the pulse voltage source 18 is open, so that no pulse voltage is applied to the metal tube 17.

Electromagnetic waves 100 reflected by the reflector 11A in the waveguide column 11 are guided toward the guiding portion 13 and propagate through a space between the guiding portion 13 and the electrically conductive tube 15A to reach the uncovered portion of the quartz tube 14. Then, an electric field is generated by the electromagnetic waves in and around the uncovered portion, i.e., in a gap between the guiding portion 13 and the electrically conductive tube 15A, and the electric field is applied to the inner space of the quartz tube 14.

When the electric field is applied to the inner space of the quartz tube 14, surface waves (electromagnetic waves) 200 are generated along the inner surface of the quartz tube 14, and thus (surface wave) plasma 300 is ignited in the inner space of the quartz tube 14. The plasma 300 is generated as a surface wave-excited plasma as the CH₄ gas is excited by the surface waves 200, and includes atoms or ions of carbon, hydrogen, argon, and silicon, and molecules of these elements and compounds, and radicals as plasma particles.

Because the electrically conductive tube 15B is arranged inside the quartz tube 14, the surface waves 200 cannot spread to the left into the inside of the electrically conductive tube 15B. Namely, the plasma 300 is confined in the uncovered portion of the quartz tube 14 as shown in FIG. 2.

The area where the plasma 300 is ignited inside the quartz tube 14 is referred to as a plasma ignition area hereinafter.

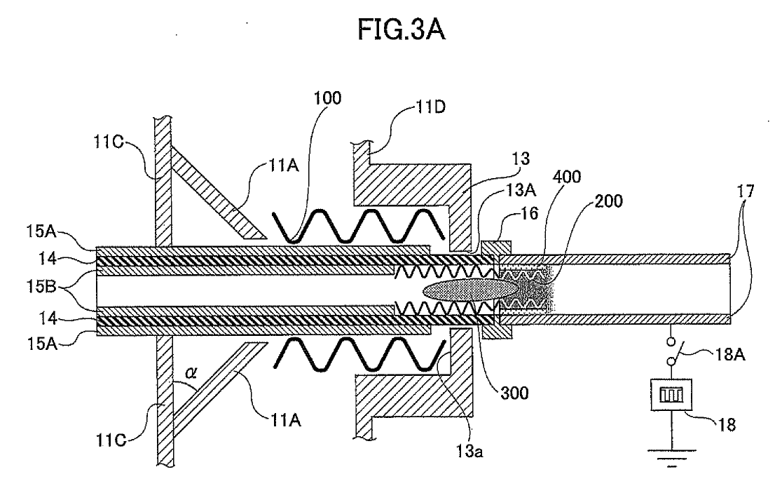

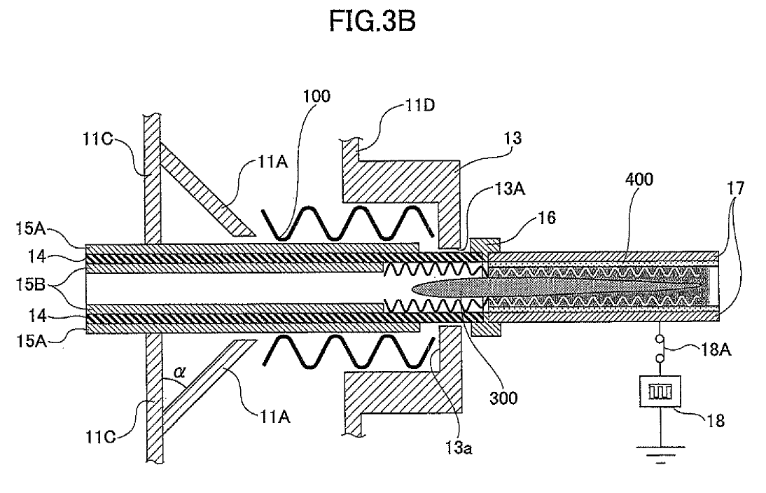

FIGS. 3A and 3B are partial enlarged views for explaining the principle of guiding plasma in the plasma process apparatus according to the first embodiment. Specifically, FIG. 3A illustrates the plasma 300 before the switch 18A is closed, and FIG. 3B illustrates the plasma 300 after the switch is closed.

Referring to FIG. 3A, sheath 400 is generated along the inner surface of the metal tube 17 only at an entrance portion of the metal tube 17 before the switch 18A is closed, and the surface waves 200 propagate along this sheath 400 into the entrance portion of the metal tube 17. When the surface waves 200 propagate into the inside of the metal tube 17, the process gases in the metal tube 17 are excited, thereby guiding the surface wave-excited plasma 300 into the entrance portion of the metal tube 17. In other words, the sheath 400 is generated between the surface wave-excited plasma 300 and the inner surface of the metal tube 17, and the surface waves 200 propagate along the boundary between the sheath 400 and the surface wave-excited plasma 300.

As stated, the surface wave-excited plasma 300 generated in the plasma ignition area can reach the entrance portion of the metal tube 17 along with the surface waves 200 before the predetermined voltage is applied to the metal tube 17.

As shown in FIG. 3B, when the switch 18A is closed and the predetermined voltage is applied to the metal tube 17, the sheath 400 in the inner space of the metal tube 17 becomes thicker and spreads along the inner surface to the other end portion of the metal tube 17.

The surface waves 200 also propagate toward the other end portion of the metal tube 17 along the sheath 400 that spreads over the inner surface of the metal tube 17 by applying the predetermined voltage to the metal tube 17.

When the surface waves 200 propagate toward the other end portion of the metal tube 17, the process gases are excited by the surface waves 200, and thus the density of the surface wave-excited plasma 300 is increased in the inner space of the metal tube 17. For example, the density of the plasma 300 is in a range of 1.0×10¹¹ cm⁻³ or more.

Specifically, because the pulse voltage supplied from the pulse voltage source 18 and applied to the metal tube 17 is synchronized with the electromagnetic waves generated by the electromagnetic wave generator 12, the surface waves 200 and the sheath 400 are in synchronization with each other, thereby facilitating the guiding of the surface wave-excited plasma 300 toward the other end portion of the metal tube 17.

As stated, according to the plasma process apparatus of the first embodiment, the metal tube 17 as an object to be processed is used as a vacuum chamber; the sheath 400 is generated over the inner surface of the metal tube 17 by applying the negative bias to the metal tube 17; and the surface waves 200 and the surface wave-excited plasma 300 are guided further into the inner space of the metal tube 17 by the sheath 400. Therefore, the coating film, such as a diamond film, can be deposited on the inner surface of the metal tube 17, even when the metal tube 17 has a long and slim tubular shape. In addition, the outer surface of the metal tube 17 is not coated with the coating film, as is shown.

Because the long slim tubular metal tube 17 having, for example, the diamond film coated on the inner surface is highly corrosion-resistive, such a metal tube 17 is preferably used in, for example, a semiconductor fabrication apparatus, specifically, used for a gas supplying line through which highly reactive and/or toxic gases flow.

While the plasma process apparatus according to the first embodiment has the cone-shaped reflector 11A inside the waveguide column 11, the reflector 11A may or may not be provided because the electromagnetic waves can be guided into the guiding portion 13 without the reflector 11A.

In addition, while the electrically conductive tube 15B is arranged inside the quartz tube 14 in the plasma process apparatus according to the first embodiment, the surface wave-excited plasma 300 can be guided into the metal tube 17 in order to deposit, for example, the diamond film on the inner surface of the metal tube 17 even when the electrically conductive tube 15B is absent.

Moreover, while the metal tube 17 is made of stainless steel in this embodiment, the metal tube 17 may be made of different metals.

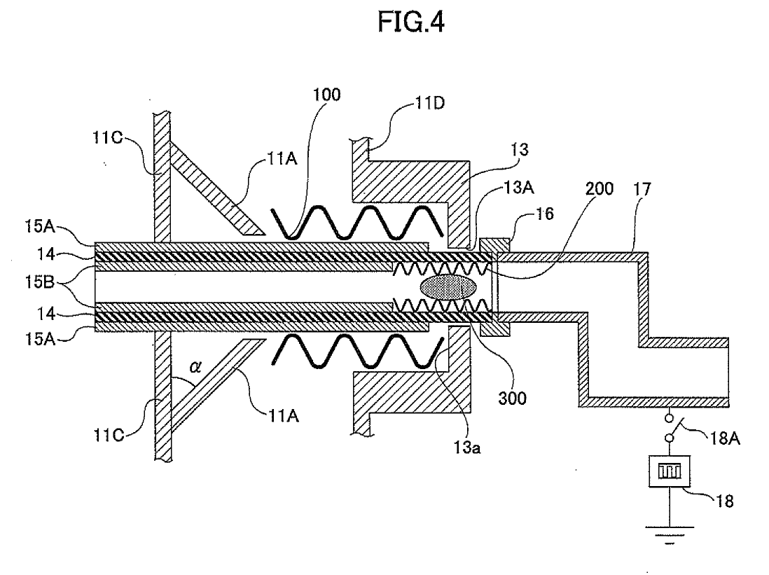

Furthermore, while the metal tube 17 is a linear tubular member in this embodiment, the metal tube 17 may be a bent tubular member as shown in FIG. 4. Additionally, the metal tube 17 may be bent at plural positions and in various ways in terms of bending angles and directions. Moreover, the metal tube 17 may be curved at plural positions and in various ways.

While the pulse voltage source 18 applies a pulse (square wave-like) negative voltage to the metal tube 17 in this embodiment, a high-frequency voltage of a sinusoidal, a triangular, or a sawtooth waveform may be applied to the metal tube 17 instead of the pulse voltage. The frequency of these voltages may be in the range of 10 Hz through 1 MHz.

In addition, another voltage source may be used in order to apply a negative direct voltage to the metal tube 17 instead of the pulse voltage source 18.

Moreover, the pulse synchronization circuit 22 is not always necessary, and the pulse voltage generated by the pulse voltage source 18 may be out of synchronization with the electromagnetic waves generated by the electromagnetic wave generator 12.

While the metal tube 17 has two open ends in this embodiment, the metal tube 17 may be a manifold having three or more open ends. In this case, one of the three or more open ends of the metal tube 17 is connected to the quartz tube 14 via the joint 16; another open end is connected to the vacuum pump 21; and the other open end(s) is closed or may be used as a gas supplying port.

### Second Embodiment

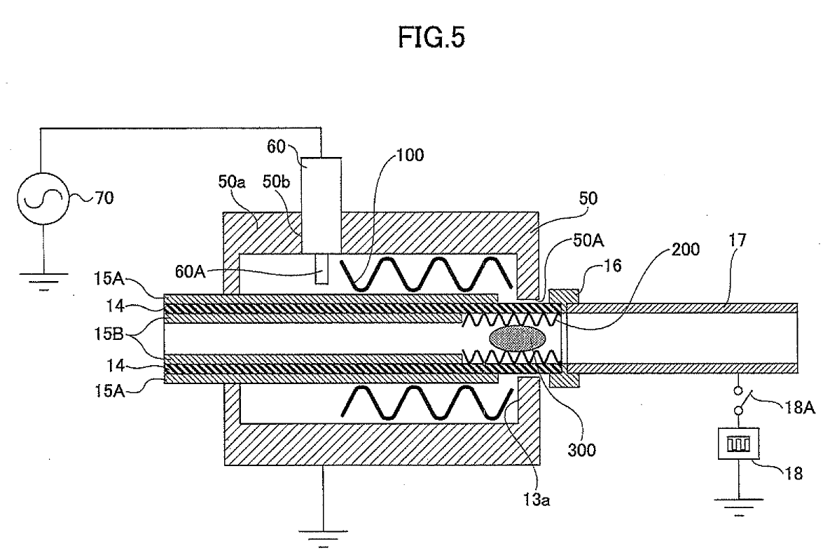

FIG. 5 shows a primary portion of a plasma process apparatus according to a second embodiment of the present invention. The plasma process apparatus according to the second embodiment includes a waveguide column 50, a coaxial cable 60, and a high-frequency voltage source 70 instead of the waveguide column 11 and the guiding portion 13 of the first embodiment. Namely, the plasma process apparatus according to the second embodiment is different from the plasma process apparatus according to the first embodiment in that the electromagnetic waves are supplied to the inside of the waveguide column 50 by supplying high-frequency power from the high-frequency voltage source 70 through the coaxial cable 60. The frequency of the electromagnetic waves in the second embodiment is set to be lower than the frequency of the electromagnetic waves in the first embodiment by a factor of ten or more.

The waveguide column 50 is formed of an electrically conductive material such as aluminum into a box shape, and the inner space of the waveguide column 50 has a rectangular cross section. The quartz tube 14, the electrically conductive tube 15A, and the electrically conductive tube 15B penetrate through the waveguide column 50. In addition, the coaxial cable 60 is inserted through a through-hole 50b formed in a side wall portion 50a. The coaxial cable 60 is stripped at the fore end and thus a cable core 60A is exposed inside the waveguide column 50. The cable core 60A is arranged so that the fore end of the cable core 60A is close to, but apart from the outer circumference of the electrically conductive tube 15A. A shield wire of the coaxial cable 60 is grounded.

An opening 50A of the waveguide column 50 corresponds to the opening 13A of the guiding portion 13 in the first embodiment. A positional relationship of the quartz tube 14, the electrically conductive tube 15A, and the electrically conductive tube 15B with respect to the opening 50A is the same as the positional relationship of the quartz tube 14, the electrically conductive tube 15A, and the electrically conductive tube 15B with respect to the opening 13A in the first embodiment. Therefore, the uncovered portion of the quartz tube 14 in the second embodiment is made in the same manner as the uncovered portion of the quartz tube 14 in the first embodiment.

In such a plasma process apparatus, when high-frequency electric power is supplied from the high-frequency voltage source 70 to the coaxial cable 60, electromagnetic waves 100 are generated in the waveguide column 50 and around the outer circumference of the quartz tube 14. Then, the surface waves 200 are generated along the inner surface of the quartz tube 14, and thus the plasma 300 is ignited.

It should be noted that the right hand side of the waveguide column 50 from the cable core 60A serves as an electromagnetic wave guiding portion that guides the electromagnetic waves emitted from the core cable 60A to the uncovered portion of the quartz tube 14 in the second embodiment.

While the plasma 300 is being generated in the quartz tube 14, when the switch 18A is closed, the sheath 400 is formed in the metal tube 17 thereby allowing the plasma 300 to be guided into the metal tube 17. This is because the surface waves 200 that propagate into the metal tube 17 with the aid of the sheath 400 excite the process gases inside the metal tube 17, thereby generating the surface wave-excited plasma 300.

With this, the coating film such as a diamond film can be deposited on the inner surface of the metal tube 17, as in the case with the first embodiment.

As stated, even when the plasma is ignited by supplying high-frequency voltage to the quartz tube 14 from the high-frequency voltage source 70 through the coaxial cable 60, the coating film such as a diamond film can be deposited on the inner surface of the metal tube 17, as in the case with the first embodiment.

### Third Embodiment

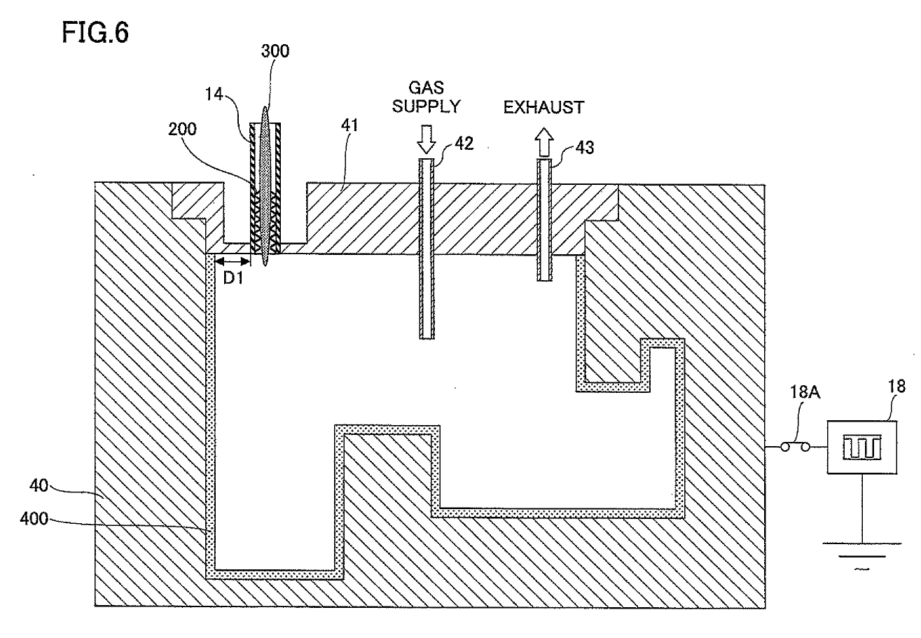

FIG. 6 is a schematic view of a primary portion of a plasma process apparatus according to a third embodiment of the present invention. The plasma process apparatus according to the third embodiment is different from the plasma process apparatus according to the first embodiment in that a chamber 40 connected to the quartz tube 14 is an object to be processed instead of the metal tube 17. While only the fore end portion of the quartz tube 14 is illustrated in FIG. 6 for the sake of simplicity, the electromagnetic waves are supplied to the quartz tube 14 through the waveguide column 11 and the guiding portion 13.

The chamber 40 has a complicated inner shape and is closed at the top by a lid 41. The lid 41 has three openings through which the quartz tube 14, a gas supplying pipe 42, and an exhaust pipe 43 are air-tightly introduced, respectively.

In addition, the chamber 40 is connected to the pulse voltage source 18 via the switch 18A, which can form the sheath 400 over the inner surface of the chamber 40.

When the sheath 400 is formed by applying the pulse voltage from the pulse voltage source 18, the surface waves 200 propagate along the inner surface of the chamber 40, and thus the process gases are excited inside the chamber 40, thereby generating the surface wave-excited plasma. Therefore, the coating film such as a diamond film can be deposited on the inner surface of the chamber 40 having such a complicated inner shape.

A distance D1 (FIG. 6) between the fore end of the quartz tube 14 and the inner surface of the chamber 40 needs to be determined so that the surface waves 200 and thus the plasma 300 can be guided to the inner surface of the chamber 40.

As stated, the coating film such as a diamond film can be formed on the inner surface of the chamber 40 having the complicated inner shape, according to the third embodiment of the present invention. When the chamber 40 so treated is used, for example, as a process chamber of a semiconductor fabrication apparatus, the inner surface of the process chamber can be protected against physical and chemical exposure of plasma and the like for processing a semiconductor wafer. Therefore, unwanted deposits on the inner surface and thus flaking of the deposits from the inner surface can be suppressed, thereby extending time-between-maintenances and prolonging the life of the process chamber.

The inner shape of the chamber 40 is not limited to the shape shown in FIG. 6, but may be variously changed. For example, the chamber 40 may have plural curved or concave portions. In addition, the chamber 40 may be a cylinder of an internal combustion engine. Namely, such a cylinder having the coating film such as a diamond film coated on the inner surface may be obtained according to the third embodiment of the present invention.

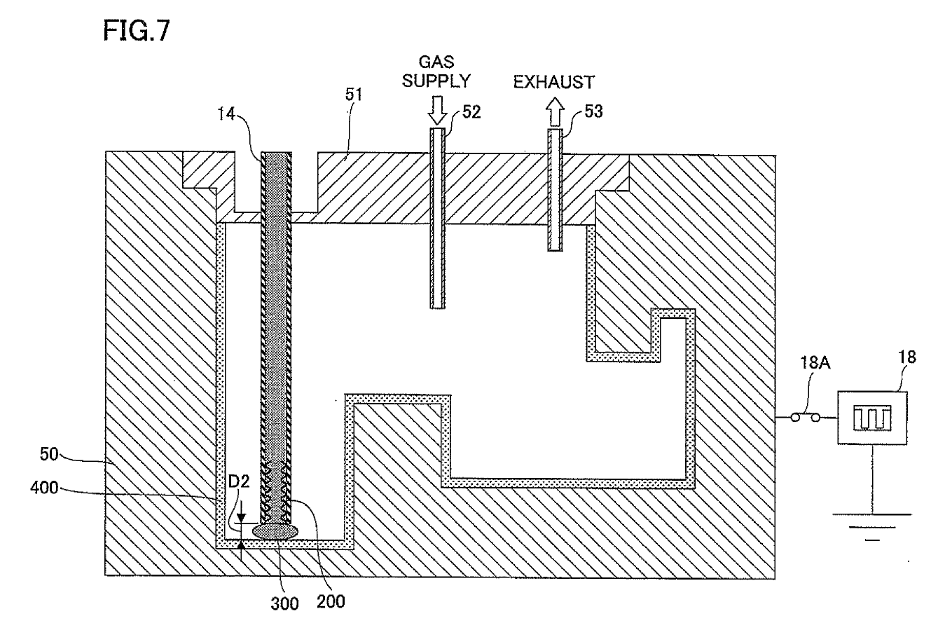

FIG. 7 is a schematic view illustrating an alternative example of the primary portion of the plasma process apparatus according to the third embodiment of the present invention. This plasma process apparatus is different from the plasma process apparatus shown in FIG. 6 in that the quartz tube 14 is extended close to the bottom surface of the chamber 40. Regarding the other members and components, the plasma process apparatuses in FIGS. 6 and 7 are the same as each other.

In the plasma process apparatus in FIG. 7, a distance D2 between the fore end of the quartz tube 14 and the bottom surface of the chamber 40 needs to be determined so that the surface waves 200 and the plasma 300 can be guided to the bottom surface and thus the inner side surface of the chamber 40.

In the alternative plasma process chamber of the third embodiment, when the pulse voltage is applied to the chamber 40 from the pulse voltage source 18 and thus the sheath 400 is formed over the inner surface of the chamber 40, the process gases are excited, thereby generating the surface wave-excited plasma inside the chamber 40. Therefore, the coating film such as a diamond film can be deposited on the inner surface of the chamber 40 having such a complicated inner shape.

While the present invention has been described in reference to the exemplary embodiments, the present invention is not limited to the specifically disclosed embodiments, but may be modified or altered within the scope of the accompanying claims.

For example, other source materials having a chemical group containing a carbon atom such as a hydrocarbon group including an alkyl group, a vinyl group, and an aryl group, an aldehyde group, a carbonyl group, and a carboxy group, instead of CH4 and TMS, as a process gas for forming a diamond film on the inner surfaces of the metal tube 17 and the chamber 40 may be used.

The present application is based on Japanese priority application No. 2008-081840 filed Mar. 26, 2008, the entire contents of which are hereby incorporated herein by reference.

What is claimed is:

1. A plasma process apparatus for processing an object to be processed, the plasma process apparatus comprising:
an electromagnetic wave generator that generates electromagnetic waves;
a vacuum vessel configured to be hermetically connected with the object to be processed, and evacuated to a reduced pressure along with the object to be processed;
an electromagnetic wave guiding portion configured to guide the electromagnetic waves generated by the electromagnetic wave generator so that plasma is ignited in the vacuum vessel;
a gas supplying portion configured to supply a process gas to the object to be processed;
an evacuation portion configured to evacuate the object to be processed; and
a voltage source configured to apply a predetermined voltage to the object to be processed so that the plasma ignited in the vacuum vessel is guided to the object to be processed.

2. The plasma process apparatus of claim 1, wherein the voltage source may be connected to an exterior of the object to be processed.

3. The plasma process apparatus of claim 1, wherein the voltage source applies the predetermined voltage in order to generate a sheath in an inner space of the object to be processed so that an inner surface of the object to be processed is processed by electromagnetic waves guided into the inner space of the object to be processed by the sheath.

4. The plasma process apparatus of claim 1, wherein the vacuum vessel is formed of a dielectric material in a tubular shape and has an electrically conductive tube accommodating the vacuum vessel, and
wherein the electromagnetic wave guiding portion surrounds the electrically conductive tube so that a gap is made between the electromagnetic wave guiding portion and the electrically conductive tube so that the electromagnetic waves are guided through the gap, thereby applying an electric field generated in the gap to the vacuum vessel.

5. The plasma process apparatus of claim 4, further comprising a waveguide that guides the electromagnetic waves generated by the electromagnetic wave generator toward the electromagnetic wave guiding portion,
wherein the vacuum vessel is arranged in order to extend from an inside to an outside of the waveguide in a direction orthogonal to a direction along which the electromagnetic waves propagate,
wherein the electrically conductive tube surrounds the vacuum vessel inside the waveguide,
wherein the electromagnetic wave guiding portion is configured as a protruding portion of the waveguide, and
wherein the vacuum vessel has a portion that is not surrounded by the electrically conductive tube, the portion being inside the protruding portion of the waveguide, so that the electric field generated in the gap between the electromagnetic wave guiding portion and the electrically conductive tube is applied to the inner space of the vacuum vessel through the portion not surrounded by the electrically conductive tube.

6. The plasma process apparatus of claim 4, further comprising a waveguide that guides the electromagnetic waves generated by the electromagnetic wave generator toward the electromagnetic wave guiding portion,
wherein the vacuum vessel penetrates through the waveguide in a direction orthogonal to an electromagnetic wave propagation direction,
wherein the electrically conductive tube surrounds the vacuum vessel inside the waveguide,
wherein the electromagnetic wave guiding portion is configured as a protruding portion of the waveguide, and
wherein the vacuum vessel has a portion that is not surrounded by the electrically conductive tube, the portion being inside the protruding portion of the waveguide, so that the electric field generated in the gap between the electromagnetic wave guiding portion and the electrically conductive tube is applied to the inner space of the vacuum vessel through the portion not surrounded by the electrically conductive tube.

7. The plasma process apparatus of claim 1, wherein the voltage source applies a pulse voltage as the predetermined voltage to the object to be processed.

8. The plasma process apparatus of claim 7, further comprising a synchronization circuit connected to the source voltage and the electromagnetic wave generator,
wherein a frequency of the pulse voltage applied to the object to be processed is the same as a frequency of the electromagnetic waves generated by the electromagnetic wave generator; and
wherein the pulse voltage is synchronized with the electromagnetic waves by the synchronization circuit.

9. The plasma process apparatus of claim 1, wherein a density of the plasma guided to the object to be processed is 1.0×10¹¹ cm⁻³ or more.

10. The plasma process apparatus of claim 1, wherein a frequency of the electromagnetic waves is from 50 MHz through 50 GHz.

11. The plasma process apparatus of claim 1, wherein a frequency of the electromagnetic waves is 2.45 GHz and a density of the plasma that is ignited by the electromagnetic waves and guided to the object to be processed is 1.0×10¹¹ cm⁻³ or more.

12. The plasma process apparatus of claim 1, wherein the vacuum vessel is made of ceramics or quartz.

13. The plasma process apparatus of claim 1, wherein the process gas includes a chemical group containing a carbon atom.

14. The plasma process apparatus of claim 1, wherein the process gas includes tetramethylsilane.

15. A plasma process method for processing an object to be processed, the method comprising steps of:
guiding electromagnetic waves to a vacuum vessel so that plasma is ignited in the vacuum vessel;
supplying a process gas to an inner space of the object to be processed;
evacuating the inner space of the object to be processed; and
applying a predetermined voltage to the object to be processed so that the plasma is guided to the inner space of the object to be processed, thereby processing an inner surface of the object to be processed.

16. The plasma process method of claim 15, wherein a sheath is formed in the inner space of the object to be processed in the step of applying the predetermined voltage to the object to be processed.

17. An object processed by a plasma process method, the method comprising steps of:
guiding electromagnetic waves to a vacuum vessel so that plasma is ignited in the vacuum vessel;
supplying a process gas to an inner space of the object to be processed;
evacuating the inner space of the object to be processed; and
applying a predetermined voltage to the object to be processed so that the plasma is guided to the inner space of the object to be processed, thereby processing an inner surface of the object to be processed.

18. The object processed by the plasma process method of claim 17, wherein the object to be processed is made of stainless steel.

19. The object processed by the plasma process method of claim 17, wherein the object is used in an atmospheric environment.

20. The object processed by the plasma process method of claim 17, wherein the object has a curved portion.
